(19) United States
(12) Patent Application Publication
(10) Pub. No.: US 2026/0022019 A1
(43) Pub. Date: Jan. 22, 2026

(54) METHOD OF MANUFACTURING A SELF-DOPED SEMICONDUCTING CARBON NANOTUBE FILM THROUGH REPETITIVE FILTRATION PROCESS, AND A HIGHLY EFFICIENT THERMOELECTRIC DEVICE BASED ON CARBON NANOTUBE FILM

(71) Applicant: UIF (University Industry Foundation), Yonsei University, Seoul (KR)

(72) Inventors: Sang-Yong JU, Gyeonggi-do (KR); Minsuk PARK, Seoul (KR)

(73) Assignee: UIF (University Industry Foundation), Yonsei University, Seoul (KR)

(21) Appl. No.: 19/273,519

(22) Filed: Jul. 18, 2025

(30) Foreign Application Priority Data
Jul. 19, 2024 (KR) 10-2024-0095491

(51) Int. Cl. C01B 32/174; C01B 32/17; H10N 10/01; H10N 10/85

(52) U.S. Cl. CPC C01B 32/174; C01B 32/17; H10N 10/01; H10N 10/85; C01B 2202/02

(57) ABSTRACT

This invention relates to a method for manufacturing semiconducting carbon nanotube (s-SWNT) films and thermoelectric (TE) devices based thereon. It specifically concerns obtaining self-doped s-SWNT films by controlling the addition of minute quantities of metallic carbon nanotubes (m-SWNTs) through a repetitive filtration (RF) process, and subsequently manufacturing high-performance TE devices based on these films.

### CROSS-REFERENCE TO RELATED APPLICATION

This application claims priority to Korean Patent Application No. 10-2024-0095491 filed on Jul. 19, 2024, and all the benefits accruing therefrom under 35 U.S.C. § 119, the contents of which in its entirety are herein incorporated by reference.

### FIELD OF THE INVENTION

The present invention relates to a method for manufacturing semiconducting single-walled carbon nanotube (s-SWNT) films and thermoelectric devices based thereon. More specifically, it concerns a method for fabricating self-doped s-SWNT films with optimized doping density by controlling the addition of a trace amount of metallic single-walled carbon nanotubes (m-SWNTs) through a repetitive filtration (RF) process, and high-performance thermoelectric devices based on these films.

### BACKGROUND OF THE INVENTION

Carbon Nanotubes (CNTs) are materials in which carbon layers, with carbon atoms arranged in a hexagonal lattice, are rolled into a cylindrical shape, forming a hollow tube. The diameter of carbon nanotubes ranges from several nanometers (nm) to tens of micrometers (μm) in length. Due to this unique structure, carbon nanotubes exhibit excellent properties in terms of strength, elastic modulus, electrical conductivity, thermal conductivity, specific surface area, and aspect ratio. For these reasons, extensive research is being conducted on carbon nanotubes as a next-generation future material.

A thermoelectric module is a device that can directly interconvert thermal energy and electrical energy by utilizing the thermoelectric phenomenon. This phenomenon involves the formation of an electric field due to the movement of charges caused by a temperature difference, or the generation of heat or cooling at the junctions of materials by passing an electric current. This thermoelectric module technology is applied in various fields, including electronic components, unmanned mobile communication base stations, and cabinets for communication electronic components. With the thin-film formation of thermoelectric semiconductors, it is expected that the economic commercialization of superconductors will become possible.

Meanwhile, self-doping refers to the phenomenon where a semiconductor material dopes itself. Doping is the process of controlling and adjusting the electrical properties of a semiconductor by introducing electrons or holes. While semiconductors generally require doping from external sources, some materials can inherently generate impurities or possess the ability to self-transfer charges. In such cases, the electrical properties of the material can be controlled without external doping, and this intrinsic doping is called self-doping.

Carbon Nanotubes (CNTs), particularly single-walled carbon nanotubes (SWNTs), are being investigated as promising thermoelectric (TE) devices. This is due to their excellent conductivity, lightweight nature, low toxicity, abundant constituent elements, and simple film fabrication and production potential. Semiconducting single-walled carbon nanotubes (s-SWNTs) have gained significant attention because their unique electronic properties, such as high mobility and sharp van Hove singularity (vHs) band structures, are advantageous for high thermoelectric (TE) conversion efficiency.

Recent research has shown that high-purity s-SWNTs can be used to create high-performance TE devices. To enhance TE performance, external dopants have been introduced to adjust doping levels. However, the introduction of external dopants often deteriorates overall TE performances and these dopants are volatile over time, which hinders the ability to maintain controlled doping levels and consistent TE performance. Therefore, the search for non-volatile and thermally stable dopants is crucial for achieving high-performance TE devices.

Meanwhile, self-doping refers to the phenomenon where a semiconductor material dopes itself [Previous Response]. For example, some semiconductor nanostructures can inherently dope themselves with electrons or holes through surface defects or oxidation. This offers the advantage of controlling the material's electrical properties without the need for external injection or extraction of charges. As such, self-doping is an important concept in the fields of nanoelectronic devices and nanoelectronics.

The disclosures of the following references are incorporated herein by reference in their entirety as if each were individually and fully set forth herein.
1. Minsuk Park, et al. “Highly Efficient Thermoelectricity Based on Self-Doped Carbon Nanotubes through the Repetitive Filtration Process” ACS Appl. Mater. Interfaces 2025, 17, 18482-18492
2. Korean patent publication no. 10-2017-0092351
3. Korean patent no. 10-1360281
4. Huang, W., et al. “Thermoelectric properties of dispersant-free semiconducting single-walled carbon nanotubes sorted by a flavin extraction method.” Chemical communications 55.18 (2019): 2636-2639.

### SUMMARY OF THE INVENTION

The present invention aims to solve the aforementioned problems by providing a method for obtaining high-purity semiconducting carbon nanotubes (s-SWNTs) and fabricating them into films, as well as thermoelectric devices based on these films.

To achieve the above objective, the present invention provides a method for manufacturing self-doped semiconducting carbon nanotube (s-SWNT) films through the addition of metallic carbon nanotubes (m-SWNTs) via repetitive filtration (RF), comprising (A) a first filtration step of filtering a dispersion containing semiconducting carbon nanotubes (s-SWNTs) and a trace amount of metallic carbon nanotubes (m-SWNTs) through a first membrane filter to obtain a first filtrate, (B) a second filtration step of filtering the first filtrate through a second membrane filter to deposit a carbon nanotube thin film on the second membrane filter, and (C) a step of separating the second membrane filter from the carbon nanotube thin film to obtain a semiconducting carbon nanotube film, wherein the pore size of the second membrane filter is smaller than that of the first membrane filter.

Through the repetitive filtration (RF) process according to the present invention, high-purity semiconducting carbon nanotube (s-SWNT) films can be obtained. Furthermore, by controlling the addition of a trace amount of metallic carbon nanotubes (m-SWNTs), the method can achieve self-doping of the s-SWNT films with an optimized doping density.

Additionally, thermoelectric devices comprising the semiconducting carbon nanotube (s-SWNT) films manufactured by the method of the present invention can exhibit high power factor (PF) and performance.

However, the effects of the present invention are not limited to those mentioned above, and other unmentioned effects will be clearly understood by a person of ordinary skill in the art from the following description.

### BRIEF DESCRIPTION OF DRAWINGS

FIG. 1 illustrates the process of manufacturing semiconducting single-walled carbon nanotube (s-SWNT) films according to the repetitive filtration (RF) process of the present invention.

FIGS. 2A to 2E show the optical characteristics of s-SWNT films measured according to the number of repetitive filtration (RF) cycles. It presents (A) UV-Vis-SWIR spectra, (B) purity of s-SWNT, (C) normalized and subtracted spectra of F0D and F1D, (D) Raman spectra of s-SWNT films at 785 nm excitation, and (E) Raman spectra of s-SWNT films at 532 nm excitation.

FIGS. 3A to 3E illustrate the self-doping characteristics of s-SWNTs induced by trace amounts of metallic single-walled carbon nanotubes (m-SWNTs) and oxygen. It shows (A) density of States (DOS) energy alignment diagrams when m-SWNTs and s-SWNTs are isolated or in contact, (B) DOS energy alignment diagrams as m-SWNTs decrease through the RF process, (C) work function (φ) of s-SWNT, (D) e^{s}₁₁/e^{s}₂₂ absorbance ratio of s-SWNT films, and (E) e^{s}₁₁/e^{s}₂₂ absorbance ratio of s-SWNT films against the linear carrier concentration (nl) of undoped s-SWNT.

FIGS. 4A to 4E show the morphological changes of SWNTs and carbonaceous impurities (CIs) analyzed by AFM. It presents (A) AFM image of F0D, (B) AFM image of F5D, (C) average length of SWNTs, (D) average height of SWNTs, and (E) average height of CIs.

FIGS. 5A to 5C illustrate the characteristics of thermoelectric (TE) devices based on s-SWNT films. It shows (A) schematic of the off-axis four-point method, (B) plot of ΔV versus ΔT for s-SWNT films, and (C) image of a TE device containing a heating wire on a Si3N4 membrane.

FIGS. 6A to 6F present the thermoelectric (TE) performance of s-SWNT films according to the number of RF cycles. It indicates (A) Seebeck coefficient (α), (B) electrical conductivity (σ), (C) thermal conductivity (κ), (D) power factor (PF), and (E) figure of merit (zT).

FIG. 7 graphically represents the TE performance of F0-F6 as a function of carrier concentration (n).

FIG. 8 shows SEM images of F1-F6, where the red-marked areas indicate carbonaceous impurities (CIs).

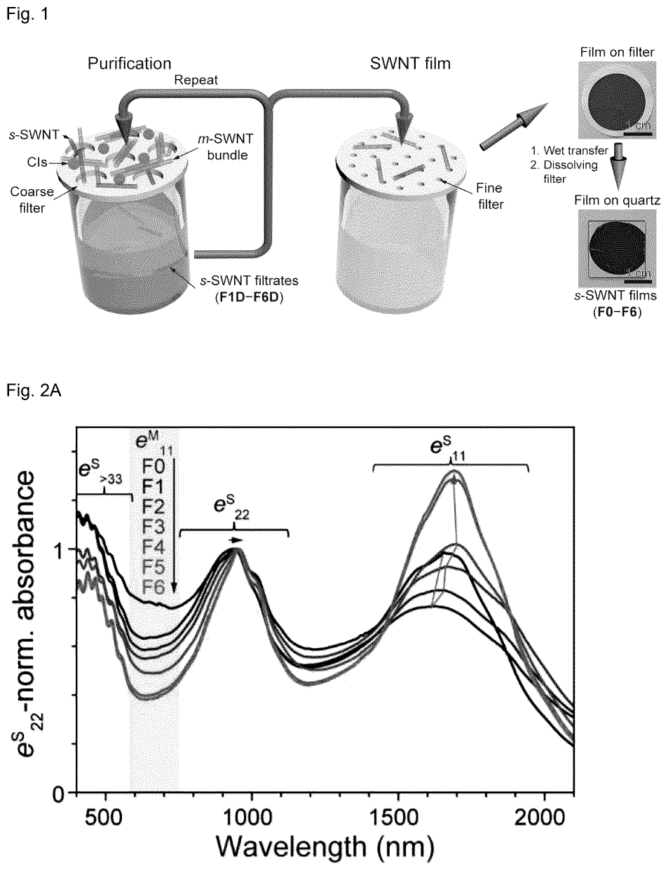

### DETAILED DESCRIPTION OF THE INVENTION

Hereinafter, embodiments of the present invention will be described in detail with reference to the drawings. Unless otherwise defined, technical or scientific terms used in this description shall denote meanings commonly understood by those of ordinary skill in the art to which the invention pertains. In describing the present invention, detailed explanations will be omitted if it is deemed that such detailed explanations may obscure the gist of the present invention.

In describing the constituent elements of the present invention, when terms such as “comprises,” “has,” “consists of,” or “is configured with” are used, other parts may be added unless “only” is explicitly used. When a constituent element is expressed in the singular, it may include the case where it encompasses the plural, unless there is a specific explicit statement to the contrary.

One aspect of the present invention relates to a method for manufacturing semiconducting carbon nanotube films and thermoelectric devices based thereon. According to the present invention, self-doped semiconducting carbon nanotubes with an optimal density can be manufactured by effectively controlling the addition of minute quantities of metallic carbon nanotubes through a repetitive filtration (RF) process. Furthermore, the semiconducting carbon nanotube films manufactured according to the present invention have a purity of over 99% and exhibit a high Seebeck coefficient, which effectively improves thermoelectric device performance.

Specifically, the method may comprise the following steps:
(A) a first filtration step of filtering a dispersion containing semiconducting carbon nanotubes and minute quantities of metallic carbon nanotubes with a first membrane filter to obtain a first filtrate, which also serves to remove impurities present in the dispersion.
(B) a second filtration step of re-filtering the first filtrate with a second membrane filter to deposit a carbon nanotube thin film on the second membrane filter, and
(C) a step of separating the second membrane filter from the carbon nanotube thin film to obtain a semiconducting carbon nanotube film.

The pore size of the second membrane filter is smaller than the pore size of the first membrane filter. Preferably, the first filtration step can be performed two or more times. The membrane filters can be a mixed cellulose ester (MCE) filter.

As the number of cycles of the repetitive filtration process increases, the purity of the semiconducting carbon nanotubes contained in the first filtrate can be enhanced. Furthermore, the doping amount of metallic carbon nanotubes within the semiconducting carbon nanotube film and the doping density can be controlled based on the number of repetitive filtration cycles, thereby varying the characteristics of the finally manufactured film depending on the cycle number.

The second filtration step (B) involves filtering the first filtrate with a second membrane filter having a pore size smaller than that of the first membrane filter, thereby depositing a carbon nanotube thin film on the second membrane filter.

By using a filter with a smaller pore size for the second membrane filter than the first, some carbon nanotubes are not completely filtered through but rather adhere to the membrane filter, forming a carbon nanotube thin film.

The step (C) involves separating the second membrane filter from the carbon nanotube thin film to finally obtain a semiconducting carbon nanotube film. Any known method capable of removing the membrane filter to obtain the carbon nanotube film can be used without limitation. For example, the second membrane filter can be dissolved and removed using an organic solvent. Specifically, this separation can be achieved by dissolving the mixed cellulose ester (MCE) filters with hot acetone/tetrahydrofuran (THF) vapor, then transferring the filter-free SWNT film onto a quartz substrate.

Furthermore, the carbon nanotube films finally manufactured according to this method can have a thickness ranging from 20 nm to 1 cm.

It was confirmed that quantitatively significant and qualitatively different effects are obtained depending on the pore size of the first membrane filter, the first filtration unit volume (the amount of one first filtration performed without replacing the membrane filter), and the number of cycles for repeating the first filtration step.

First, since individualized carbon nanotubes can possess excellent mechanical and electrical properties, the pore size of the first membrane filter can be an important process condition for obtaining carbon nanotubes existing as individualized strands through dispersion. According to an embodiment of the present invention, the pore size of the first membrane filter may preferably be 0.3 to 0.6 μm, and more preferably 0.4 to 0.5 μm.

The pore size less than 0.3 μm may cause most carbon nanotubes to remain as residue on the filter surface without being filtered. If it exceeds 0.6 μm, even large bundled carbon nanotubes are entirely filtered and included in the first filtrate, making it undesirable as the effect of obtaining individualized carbon nanotubes through the first filtration step cannot be achieved. On the other hand, it was confirmed that when using a membrane filter with a pore size satisfying the range of 0.3 to 0.6 μm, a filtration effect that can maximize the yield of carbon nanotubes existing as individualized strands can be obtained.

As the first filtration step continues, unfiltered carbon nanotubes and impurities gradually accumulate on the surface of the first membrane filter, leading to pore clogging and a loss of filtration effect. Therefore, it is preferable to replace the filter with a new one after filtering a certain amount. According to an embodiment of the present invention, it is preferable to replace the first membrane filter after filtering 3 to 8 mL, and more preferably 4 to 6 mL, of the dispersion through it.

It was confirmed that when the unit volume of this first filtration satisfies a preferable range of 3 to 8 mL, in addition to the filtration effect by the membrane filter, a self-sieving effect can also be obtained from the unfiltered carbon nanotubes attached to the filter surface through repetitive filtration, thereby synergistically improving the purity of semiconducting carbon nanotubes. Conversely, if the unit volume of the first filtration falls outside the range of 3 to 8 mL, this effect cannot be achieved, which is undesirable.

Additionally, by adjusting the number of cycles for repeating the first filtration step, the p-doping density self-doped into the semiconducting carbon nanotube film by metallic carbon nanotubes can be controlled.

As the number of cycles increases, the content of metallic carbon nanotubes and the degree of p-doping can gradually decrease. Therefore, if no additional doping treatment with external dopants is performed through a subsequent process, it is preferable to repeat the first filtration step for a number of cycles within a range where p-doping does not completely diminish.

According to another embodiment, specifically when \textcircled{a} the pore size of the first membrane filter is 0.4 to 0.6 μm, \textcircled{b} the unit volume of the first filtration is 4 to 6 mL, and \textcircled{c} the first filtration step is repeated 2 to 4 times, it was confirmed that the doping amount within the semiconducting carbon nanotube film can be adjusted to a level that maximizes the thermoelectric properties of the device even without additional subsequent doping treatment.

According to yet another embodiment, specifically when \textcircled{a} the pore size of the first membrane filter is 0.4 to 0.6 μm, \textcircled{b} the unit volume of the first filtration is 4 to 6 mL, \textcircled{c} the first filtration step is repeated 6 or more times, the purity of the semiconducting carbon nanotubes finally obtained through filtration can be maximized, although the density of self-doping p-doping may decrease, thereby greatly enhancing the efficiency of treatment processes for improving thermoelectric properties in subsequent steps. For example, it was confirmed that subsequent doping treatment using external dopants can show the effect of maximizing thermoelectric properties with a small amount of dopants.

Prior to step (A), it may further include (a-1) a step of preparing a carbon nanotube dispersion by ultrasonically treating a mixture containing carbon nanotubes, a surfactant, and a dispersion medium; and (a-2) a step of separating metallic carbon nanotubes from semiconducting carbon nanotubes from the carbon nanotube dispersion.

The step (a-1) is for preparing a carbon nanotube dispersion. By additionally adding a surfactant to the carbon nanotube solution, uniform dispersion of carbon nanotubes can be induced, making it easier to disperse the carbon nanotubes. Since carbon nanotubes mostly exist in bundle forms during the synthesis stage, it is important to minimize the bundle size of the carbon nanotubes and disperse them to fully utilize their excellent mechanical and electrical properties.

The carbon nanotubes of the present invention can be used either by synthesis or by purchasing commercially available ones. The synthesis of carbon nanotubes can be performed by generally well-known methods and is not particularly limited. For example, it may include arc discharge, laser ablation, Chemical Vapor Deposition (CVD), or High-Pressure Carbon Monoxide (HiPco) disproportionation. Furthermore, the diameter of the carbon nanotubes used in the present invention can typically be 0.5 to 2.0 nm, but is not limited thereto.

When carbon nanotubes are synthesized using chemical vapor deposition (CVD), which is the most representative among conventional carbon nanotube synthesis methods, it is difficult to selectively produce carbon nanotubes with desired properties. Therefore, carbon nanotubes are generally grown as a mixture of metallic carbon nanotubes and semiconducting carbon nanotubes.

Furthermore, with current technology, regardless of the synthesis method, metallic carbon nanotubes and semiconducting carbon nanotubes are produced in a mixed form. Therefore, a mixture of metallic carbon nanotubes and semiconducting carbon nanotubes is used, and they can be separated and applied appropriately for various applications.

The step (a-2) is for separating these carbon nanotubes into metallic carbon nanotubes and semiconducting carbon nanotubes, and any known technique capable of separating them can be used without limitation.

Furthermore, examples of a way of separation may without limitation include centrifuging the carbon nanotube dispersion to separate it into a sediment containing metallic carbon nanotubes and a supernatant containing semiconducting carbon nanotubes.

Centrifugation is the most representative method for separating metallic carbon nanotubes and semiconducting carbon nanotubes. By centrifuging the carbon nanotube dispersion, metallic impurities, carbonaceous impurities, and most of the metallic carbon nanotubes contained in the sediment can be removed, and semiconducting carbon nanotubes contained in the supernatant can be separated and obtained. The separated supernatant contains semiconducting carbon nanotubes, a small amount of metallic carbon nanotubes, and a solvent, and its purity can be 95% or higher. Moreover, to achieve high purity, only 80% of the supernatant can be collected and used.

The centrifugation can be performed at a speed of 1,000 g to 50,000 g (g=9.8 m/s2) for 1 to 3 hours, and more preferably at a speed of 3,000 g to 7,000 g for 1.5 to 2.5 hours. If the centrifugation speed is less than 1,000 g, the processing time for separating carbon nanotubes into supernatant and sediment may be prolonged, and if it exceeds 50,000 g, the purity of the obtained semiconducting or metallic carbon nanotubes may decrease.

The step (C) may additionally include (c-1) a step of placing the second membrane filter, on which the carbon nanotube thin film is deposited, onto a substrate and applying pressure to attach the carbon nanotube thin film to the substrate; and (c-2) a step of placing the substrate with the attached carbon nanotube thin film into a reflux chamber and dissolving and removing the secondary membrane filter. The secondary membrane filter can be dissolved by one or more vapors selected from the group consisting of acetone, tetrahydrofuran, and mixtures thereof.

According to one embodiment of the present invention, a quartz substrate can be used as the substrate. As an example, before applying pressure, an additional substrate can be placed on top to create a sandwich-type dummy glass to fix the membrane filter, and then pressure can be applied to attach it to the substrate. The type of substrate used is not limited, as long as it is a commonly used material. For instance, transparent inorganic substrates such as glass, quartz, or silicon wafers, or transparent conductive substrates such as polymer films like poly(methyl methacrylate), polystyrene, or polydimethylsiloxane, can be used.

Furthermore, according to a preferred embodiment of the present invention, the substrate with the attached semiconducting carbon nanotube film is placed into a custom-made reflux chamber. Using hot vapor, only the secondary membrane filter is dissolved and removed, and the semiconducting carbon nanotube film attached to the substrate can be obtained. When the filter dissolves, white residue can be observed flowing off, and it is preferable to continue this process for about two days for complete removal of the membrane filter.

Additionally, to dissolve the membrane filter, it is preferable to use one or more vapors selected from the group consisting of acetone, tetrahydrofuran, and mixtures thereof. The use of vapor from a mixture of acetone and tetrahydrofuran is most preferable.

In the step (A), the mass ratio of the carbon nanotubes to the surfactant can be 1:0.5-1.5, and more preferably 1:0.8-1.2. If the mass ratio of the carbon nanotubes to the surfactant is less than 1:0.5, the dispersibility of the carbon nanotube dispersion may decrease, and if it exceeds 1:1.5, the rate of improvement in dispersion power due to the addition of surfactant may decrease.

The carbon nanotubes (CNTs) used are anisotropic and can have various structures. Specifically, single-walled, double-walled, and multi-walled carbon nanotubes can be used, either individually or in a mixture of two or more, and most preferably, single-walled carbon nanotubes (SWNTs) can be used. Furthermore, carbon nanotubes can also include those with functional groups formed on their surface, and their use is not particularly limited.

Typically, single-walled carbon nanotubes exist as a mixture of semiconducting single-walled carbon nanotubes and metallic single-walled carbon nanotubes. The type or structure of single-walled carbon nanotubes, such as metallic or semiconducting, can be defined by their chiral (n, m) vector, which describes how the graphene sheet is rolled into a cylinder. That is, single-walled carbon nanotubes exhibit properties of either a conductor (metallic) or a semiconductor depending on their chirality. More specifically, they exhibit metallic properties in an arm-chair structure and semiconducting properties in a zig-zag structure. Particularly, semiconducting single-walled carbon nanotubes have a one-dimensional structure where the energy gap varies with diameter, allowing them to exhibit unique quantum effects.

The surfactant can be one or more selected from the group consisting of FMN (flavin mononucleotide), FC12 (N-dodecyl flavin), FC16 (N-hexadecyl flavin), FC20 (N-eicosyl flavin), and mixtures thereof. Specifically, using FC12 (N-dodecyl flavin) is most preferable because it provides the most superior dispersion effect for carbon nanotubes and further facilitates the formation of separated solutions through the ultrasonication process and centrifugation.

Another aspect of the present invention relates to a thermoelectric device comprising the semiconducting carbon nanotube film prepared according to the present invention. The thermoelectric device comprising the semiconducting carbon nanotube film of the present invention can be used without limitation if it is a thermoelectric device or thermoelectric material comprising a carbon nanotube film among known technologies.

### EXAMPLES

Hereinafter, preferred embodiments are presented to aid in the understanding of the present invention. However, these embodiments are intended to explain the present invention more specifically, and the scope of the present invention is not limited thereby. It will be obvious to those with ordinary knowledge in the art that various changes and modifications are possible within the scope and technical spirit of the present invention.

### Example 1: Preparation of s-SWNT Film (F1)

### 1-1) Preparation of Carbon Nanotube Dispersion (F0D)

1 mg of plasma-grown single-walled carbon nanotubes (SWNTs) with a diameter (dt) distribution of 1.3±0.35 nm and 1 mg of dodecyl flavin (FC12) are thoroughly dehydrated. This mixture is then added to 4 mL of p-xylene to prepare the carbon nanotube mixed solution.

For initial mixing, the mixture is subjected to bath sonication for 5 minutes, followed by tip sonication for 1 hour to prepare the dispersion. The dispersion is centrifuged at 5,000 g for 2 hours to remove impurities and most of the metallic single-walled carbon nanotubes (m-SWNTs) contained in the precipitate.

80 volume % of the supernatant containing semiconducting single-walled carbon nanotubes (s-SWNTs) is carefully collected, and this supernatant is named F0D56.

### 1-2) First (Primary) Filtration and Preparation of First Filtrate (F1D-F6D)

A 0.45 μm pore-sized MCE membrane filter is installed in a filtration apparatus to perform the first filtration of F0D, and the resulting first filtrate is named F1D6. During this process, a total of 70 mL of F0D stock dispersion is filtered by replacing the filter after every 5 mL of F0D filtration.

To prepare s-SWNT films, small portions (8 mL) of the F1D obtained in the previous step are set aside for subsequent processes, such as film preparation and other characterizations.

The remaining F1D after separation is filtered again using the same method as described above. This process is continuously repeated, and the filtrates obtained according to the number of repetitive filtrations are named F2D-F6D7. For each of these obtained filtrates (F2D-F6D), 8 mL is separated to prepare for subsequent processes.

1-3) Second (Secondary) Filtration and Preparation of s-SWNT Film (F1)

First, a 0.1 μm pore-sized MCE membrane filter is installed in a filtration apparatus, and 5 mL of F1D is filtered to deposit an s-SWNT film onto the surface of the membrane filter.

Before the film is completely dry, the membrane filter is positioned onto a quartz substrate (2.5 cm×2.5 cm×1 mm) coated with 20 μL of deionized water. Another substrate (dummy slide glass) is then placed on top, creating a sandwich-like structure.

The dummy slide glass is pressurized for a few seconds to adhere the s-SWNT film-deposited membrane filter to the substrate, and the opposite substrate (dummy slide glass) is then separated and removed.

After removing the residues at the rim of the membrane, the substrate is quickly loaded into a custom-made solvent reflux chamber to dissolve the membrane filter using hot acetone/tetrahydrofuran (THF) vapor. During this process, the dissolved filter becomes a whitish residue that spills from the membrane.

The right above process is continued for two full days to completely dissolve and remove the membrane filter. The film is then dried for a certain period to obtain it, and the obtained film is named F1.

### Example 2: Preparation of s-SWNT Film (F2)

An s-SWNT film was prepared following the procedure described in Example 1, except that F2D was used instead of F1D, and the obtained film was named F2.

### Example 3: Preparation of s-SWNT Film (F3)

An s-SWNT film was prepared following the procedure described in Example 1, except that F3D was used instead of F1D, and the obtained film was named F3.

### Example 4: Preparation of s-SWNT Film (F4)

An s-SWNT film was prepared following the procedure described in Example 1, except that F4D was used instead of F1D, and the obtained film was named F4.

### Example 5: Preparation of s-SWNT Film (F5)

An s-SWNT film was prepared following the procedure described in Example 1, except that F5D was used instead of F1D, and the obtained film was named F5.

### Example 6: Preparation of s-SWNT Film (F6)

An s-SWNT film was prepared following the procedure described in Example 1, except that F6D was used instead of F1D, and the obtained film was named F6.

### Comparative Example 1: Preparation of s-SWNT Film (FO) without Initial Filtration

An s-SWNT film was prepared following the procedure described in Example 1, except that F0D was used instead of F1D, and the obtained film was named F0.

### Experimental Example 1: Measurement of Optical Properties of s-SWNT Films

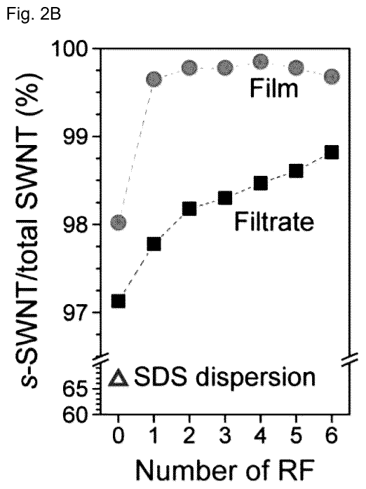

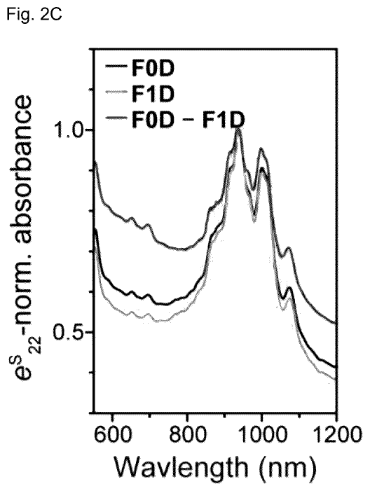

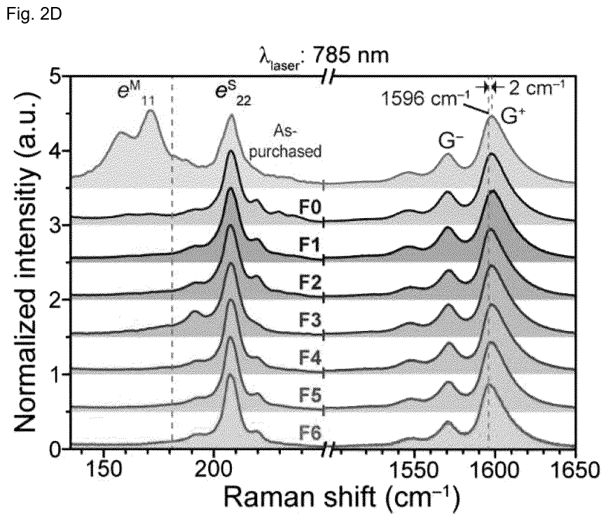

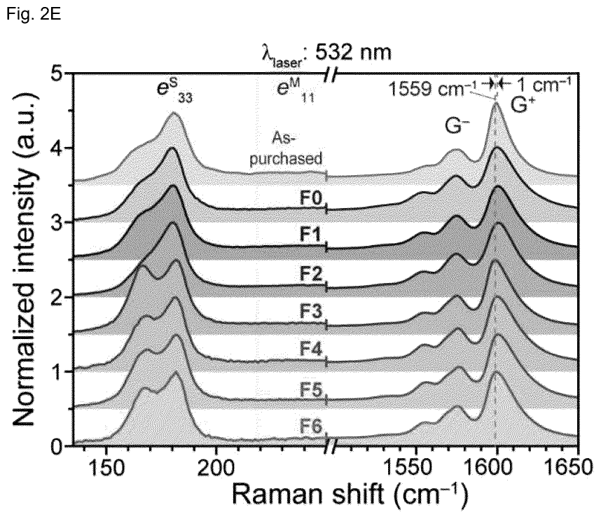

The optical properties of s-SWNT films, prepared in the Examples and the Comparative Examples, were measured based on the number of repetitive filtration (RF) cycles. The results are presented in FIG. 2.

FIG. 2 (A) shows the UV-vis-short-wavelength infrared (SWIR) absorption spectra. As shown in FIG. 2(A), a notable absence of peaks and a substantial reduction in the background absorption in the e^{M}₁₁ region can be confirmed with an increasing number of RF cycles from F0 to F6. These results underscore the effectiveness of the RF process in selectively eliminating m-SWNTs and FC12.

FIG. 2(B) graphically represents the s-SWNT purity of the s-SWNT films prepared in the Examples. It can be confirmed that the purity of s-SWNTs shows an increasing trend with an increasing number of RF cycles. Specifically, all s-SWNT films F1-F6, prepared through the primary and the secondary filtrations, consistently exhibit high s-SWNT purity exceeding 99%. These results confirm that the RF process is an effective method for achieving high-purity s-SWNTs.

FIG. 2(C) illustrates the normalized absorption spectra of F0D and F1D, and their subtracted spectrum. As shown in FIG. 2(C), it can be confirmed that the e^{M}₁₁ and background absorption of the normalized spectrum are smaller compared to the subtracted spectrum. The e^{M}₁₁ primarily originates from carbonaceous impurities (CIs). This indicates that the RF process is effective in removing CIs with widths of up to a few tens of nanometers.

Furthermore, FIG. 8 provides a series of scanning electron microscope (SEM) images of F1-F6. It can be visually confirmed that CIs (marked by transparent red) are effectively removed with an increasing number of RF cycles. This observation affirms that the RF process successfully eliminates both minute m-SWNTs and CIs.

FIGS. 2(D) and 2(E) present the Raman spectra of s-SWNT films investigated by two laser lines, with 2(D) and 2(E) analyzed by a 785 nm and a 532 nm laser, respectively. In these graphs, the left side displays the Radial Breathing Mode (RBM) region, and the right side represents the G-band region.

As depicted in FIG. 2(D), for the 785 nm excitation, the 181-235 cm⁻¹ region, corresponding to smaller-diameter s-SWNTs, exhibits intense RBM signals. Conversely, the 135-181 cm⁻¹ region, which is associated with larger-diameter m-SWNTs, shows nearly depleted peaks. This trend of peak depletion becomes more pronounced with an increasing number of RF cycles, with signal levels decreasing to the noise level.

Furthermore, as shown in FIG. 2(E), for 532 nm irradiation, s-SWNTs display various bands within the 135-200 cm⁻¹ region. In contrast, the m-SWNT region (201-250 cm⁻¹) shows almost no peaks, and the signals from this region approach zero as the number of RF cycles increases.

Therefore, through the results of this Experimental Example 1 and FIG. 2, it can be confirmed that as the number of RF cycles increases, impurities and m-SWNTs are effectively removed, leading to a higher purity of s-SWNTs.

### Experimental Example 2: Measurement of Self-Doping Characteristics of s-SWNTs

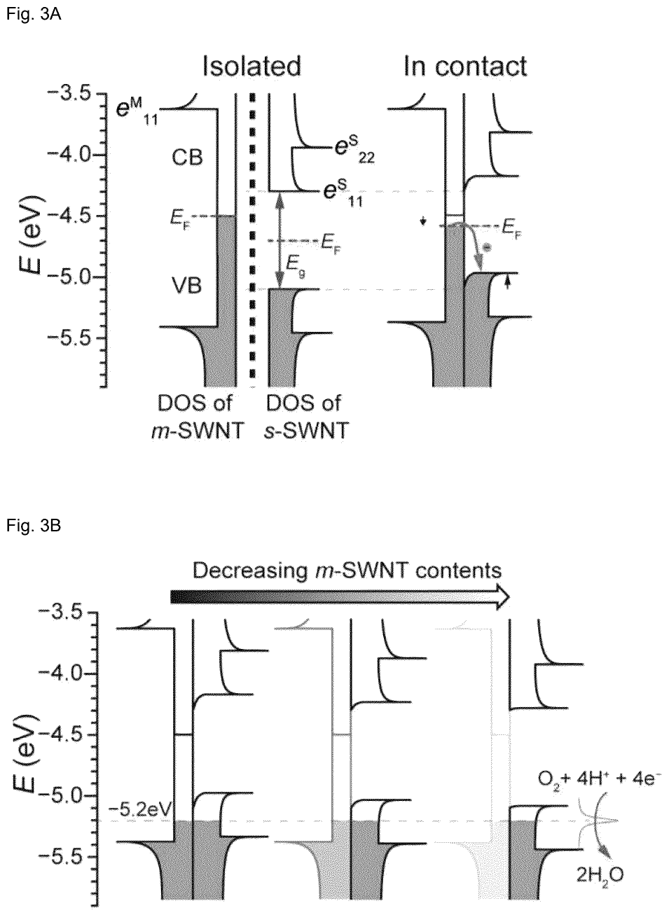

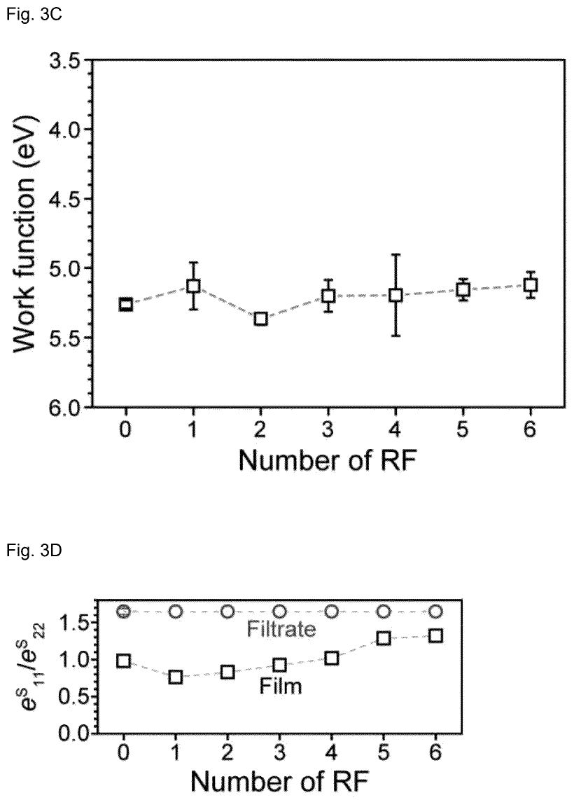

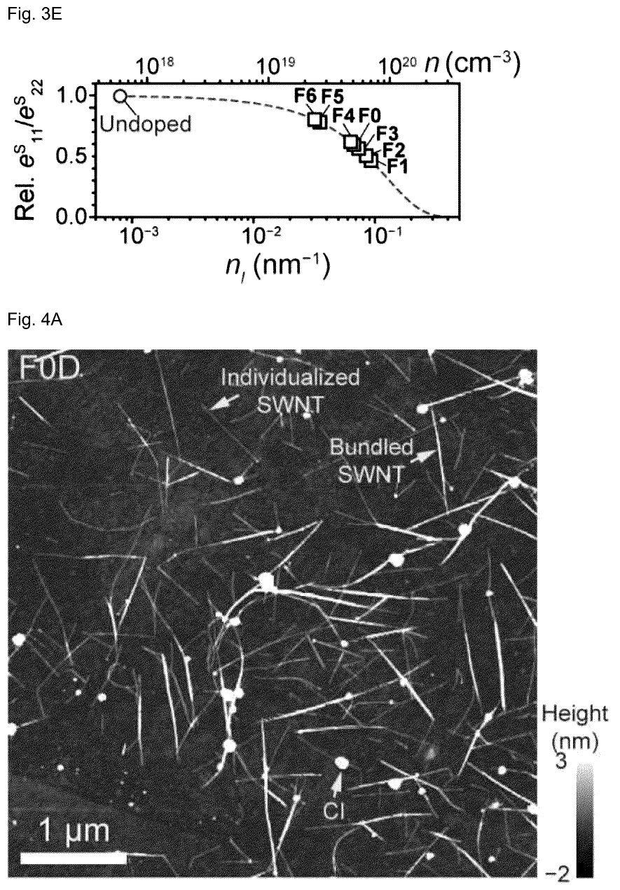

For the s-SWNT films prepared in the Examples and the Comparative Examples, the self-doping characteristics of s-SWNTs by trace amounts of m-SWNTs and oxygen were measured and presented in FIG. 3.

FIG. 3(A) schematically illustrates the DOS energy alignment diagrams when m-SWNTs and s-SWNTs are isolated or in contact. As shown in FIG. 3(A), upon contact between the two SWNTs, initially in an undoped state, electrons transfer from m-SWNT to s-SWNT, establishing Fermi level (EF) equilibrium. This also indicates band pinning and band bending of the DOS of s-SWNTs, through which it can be understood that all van Hove singularities (vHs) of s-SWNTs are elevated with respect to vacuum, while the electrons of m-SWNTs remain fixed.

FIG. 3(B) schematically illustrates the DOS energy alignment diagram when the m-SWNT content decreases through the RF process. As shown in FIG. 3(B), it can be confirmed that s-SWNTs lose band bending as the m-SWNT content decreases. At this point, the redox energy of the O₂/H₂O couple relative to vacuum must be considered, which has been reported as −5.24 eV in pH 7 solution and approximately −5.3 eV in air-saturated water. Through these results, it can be observed that the s-SWNT film, initially heavily positively (p)-doped due to the elevated e^{s}₁₁, gradually experiences a decrease in p-doping as the m-SWNT content is reduced by the RF process and the band bending of s-SWNTs diminishes.

FIG. 3(C) graphically represents the work function (φ) trend of s-SWNTs obtained through UPS measurements. As shown in FIG. 3(C), the work function of F0-F6 samples shows a value of approximately 5.2±0.1 eV with no significant change as the number of RF cycles increases from 0 to 6.

FIG. 3(D) shows the e^{s}₁₁/e^{S}₂₂ absorbance ratio for the s-SWNT filtrates and films. As shown in FIG. 3(D), it can be confirmed that the average absorbance ratio for s-SWNT filtrates (F0D-F6D) is 1.65±0.04, while that for s-SWNT films (F0-F6) fluctuates between 0.77 and 1.32.

FIG. 3(E) graphs the relative absorbance ratio of e^{s}₁₁/e^{s}₂₂ versus nl for s-SWNT films, using the values from FIG. 3(D) and normalized against undoped SWNTs. As shown in FIG. 3(E), the nl values for F1-F6 gradually decrease from 9.3×10² nm⁻¹ to 3.2×10² nm⁻¹ following the curve of the graph.

### Experimental Example 3: AFM Measurement of SWNTs

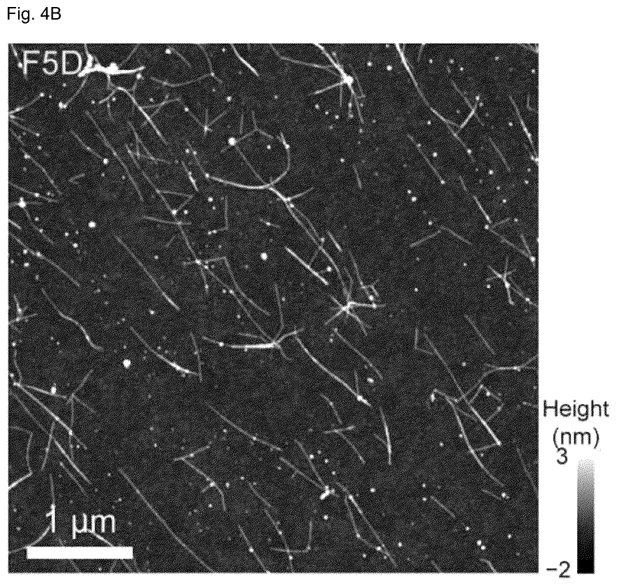

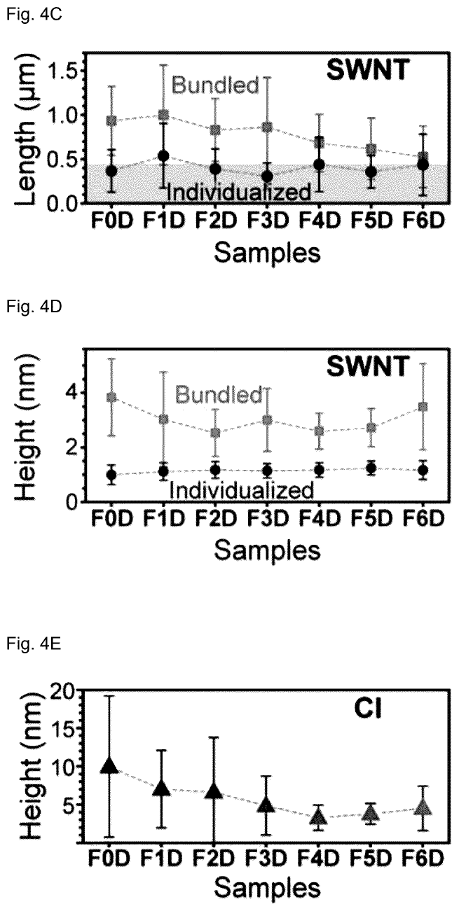

To investigate the morphological changes of SWNTs and CIs during the RF process, as per the preparation examples of the present invention, AFM analysis was conducted and presented in FIG. 4.

FIGS. 4(A) and 4(B) display AFM analysis images of F0D and F5D, respectively, where brighter colors indicate higher elevations. As shown in FIG. 4(A), F0D exhibits a relatively large number of sizable CIs and bundled SWNTs, whereas FIG. 4(B) for F5D reveals numerous smaller CIs and individualized SWNTs.

FIG. 4(C) presents the average length of bundled or individualized SWNTs, 4(D) shows their average height, and 4(E) indicates the average height of CIs. The shaded region in FIG. 4(C) denotes the pore size of the primary membrane filter of the present invention, which is 0.45 μm.

As shown in FIG. 4(C), with an increasing number of RF cycles, the average length of bundled SWNTs shortens from 0.93±0.39 to 0.53±0.35 μm. In contrast, the average length of individualized SWNTs remains approximately 0.5 μm, closely matching the filter's pore size.

Furthermore, as depicted in FIG. 4(D), the average height of bundled SWNTs decreases from 3.8±1.4 nm to 2.5±0.9 nm and then increases to 3.5±1.6 nm. Conversely, the height of individualized SWNTs remains at approximately 1.1 nm.

Additionally, as shown in FIG. 4(E), the average size of CIs decreases with an increasing number of RF cycles, which is consistent with the SEM measurement results.

Therefore, through the above experimental example and FIG. 4, it can be confirmed that the RF process is effective not only in reducing the size of CIs but also in removing long bundled SWNTs.

### Experimental Example 4. Measurement of Thermoelectric (TE) Device Characteristics of s-SWNT Films

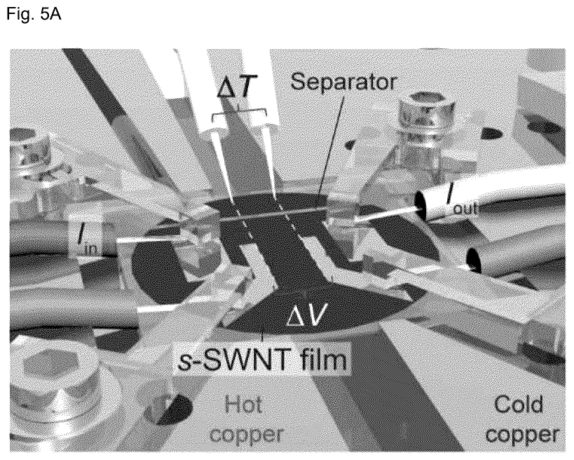

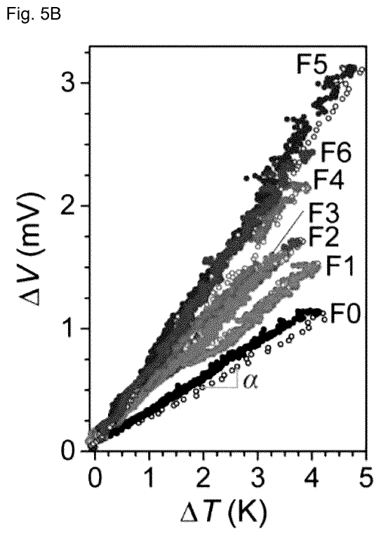

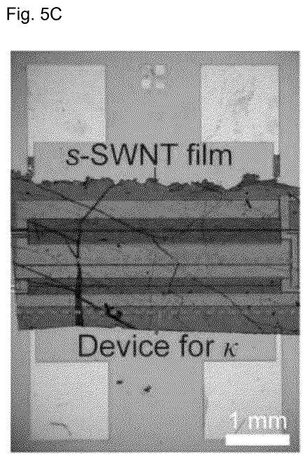

For the s-SWNT films prepared according to the examples and comparative examples of the present invention, the characteristics of thermoelectric devices based on s-SWNT films are presented in FIGS. 5 to 7.

FIG. 5(A) schematically illustrates the method utilizing the off-axis four-point technique for measuring α.

FIG. 5(B) shows the graph of δV against δT for s-SWNT films as a function of the number of RF cycles. As depicted in FIG. 5(B), it can be confirmed that a positive thermovoltage is exhibited as the temperature difference increases. This indicates that the s-SWNT film demonstrates the Seebeck effect of p-type doping originating from m-SWNTs and oxygen.

FIG. 5(C) displays an image of a TE device, incorporating a heating wire on a thin Si3N4 membrane, for the K measurement of s-SWNT films.

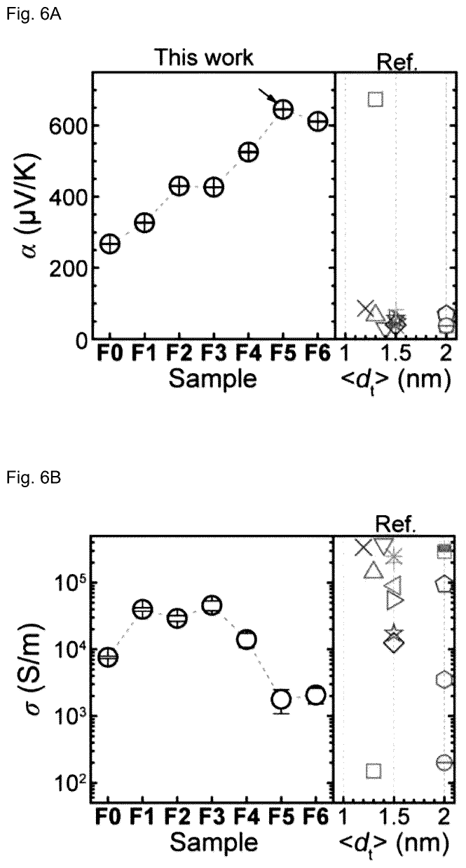

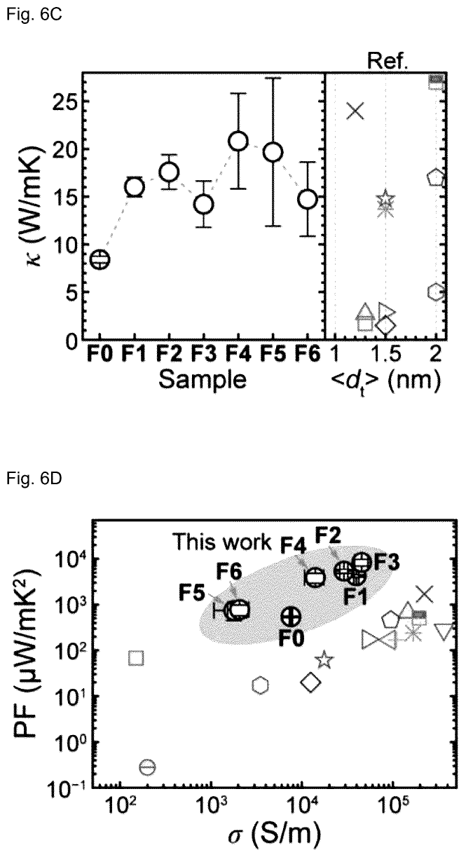

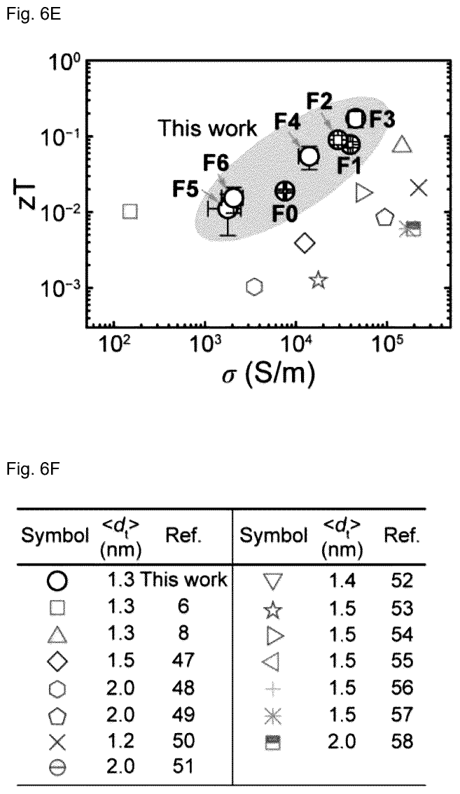

FIG. 6 illustrates the TE performance of s-SWNT films based on the number of RF cycles, where 6(A) represents α (Seebeck coefficient), 6(B) represents σ (electrical conductivity), and 6(C) represents κ (thermal conductivity). FIGS. 6(D) and 6(E) show PF (power factor) and zT (dimensionless figure of merit representing TE performance) against σ, respectively.

As shown in FIG. 6(A), it can be confirmed that as the number of RF cycles increases, α linearly increases from 268±1 μV/K (F0) to 645±1 μV/K (F5), demonstrating approximately a 2.4-fold difference. The highest α is comparable to that of PFO-derivative SWNT films with a similar diameter (dt) to the examples, and is lower than the theoretically highest value reported to date, which is 810 μV/K. Furthermore, it can be observed that the α value of F5 is almost 10 times higher than the previously known average value of SWNTs with an average dt of 1.5 nm, which is 40-70 μV/K. These results indicate that a high s-SWNT purity of over 98% is essential for enhancing α.

As shown in FIG. 6(B), σ exhibits a maximum value of 45,570±7,700 S/m at F3, demonstrating approximately a 26-fold difference compared to the minimum value. It can be confirmed that σ is proportional to the carrier concentration n according to the equation σ=μen, which also aligns with the results in FIG. 2(A) and FIG. 3(D).

As presented in FIG. 6(C), the trend of κ is similar to that of σ, showing a maximum value of 21±5 W/m·K at F4, while the values for other films generally tend to decrease.

As depicted in FIGS. 6(D) and 6(E), the calculated PF and zT values, based on the results from FIGS. 6(A), 6(B), and 6(C), reach their maximum at F3, with values of 8,309±1,404 μW/m·K² and 0.17±0.04, respectively. Notably, these values represent a significant increase compared to the previously reported highest values (705 μW/m·K² and 0.076). Therefore, it can be understood that the doping state and high α and σ values play a crucial role in enhancing PF and zT.

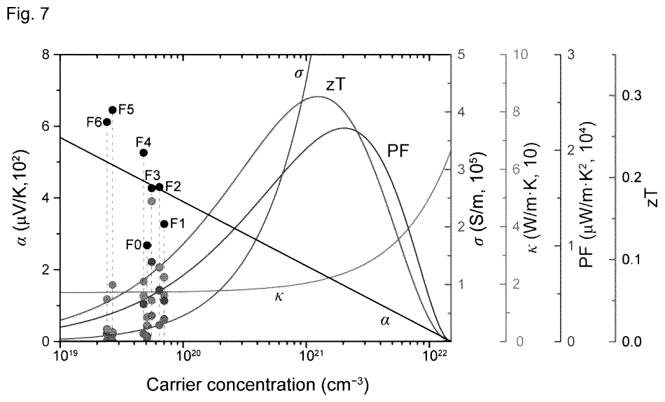

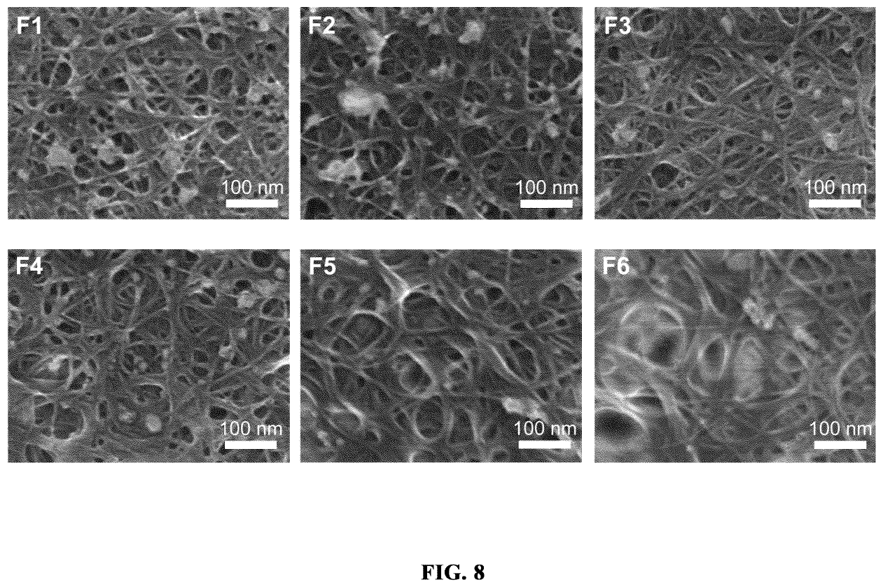

FIG. 7 graphically illustrates the TE performance of F0-F6 as a function of n. As shown in FIG. 7, it can be observed that the theoretically predicted TE performance curves, including α, σ, κ, PF, and zT, generally do not align well with the actual measured values. This discrepancy can be attributed to the changes in the purity level of s-SWNT films, m-SWNT, and CI contents, along with the decreasing s-SWNT bundles. These results suggest that minimal changes in the film constituents lead to a predictable n as a function of m-SWNT content. Nevertheless, FIG. 7 confirms that the RF process can control the n of s-SWNTs and approach the optimal zT value. Consequently, it can be concluded that increasing the s-SWNT density, such as through aligned s-SWNTs rather than random network films, would be a method to significantly improve TE performance.

The present invention is not limited to the aforementioned embodiments, and its scope of application is diverse. Furthermore, it is apparent that any person skilled in the art to which the present invention pertains can implement various modifications without departing from the gist of the present invention as defined in the claims.

What is claimed is:

1. A method for manufacturing a carbon nanotube film, the method comprising:
(A) a first filtration step of filtering a dispersion comprising semiconducting carbon nanotubes and a trace amount of metallic carbon nanotubes with a first membrane filter to obtain a first filtrate;
(B) a second filtration step of filtering the first filtrate with a second membrane filter to deposit a carbon nanotube thin film on the second membrane filter; and
(C) a step of separating the second membrane filter and the carbon nanotube thin film to obtain the carbon nanotube film;
wherein the pore size of the second membrane filter is smaller than the pore size of the first membrane filter.

2. The method according claim 1, wherein the first filtration step is performed at least twice.

3. The method according to claim 1, wherein the pore size of the first membrane filter is 0.3 to 0.6 μm.

4. The method according to claim 1, wherein the unit volume amount of the first filtration is 3 to 8 mL.

5. The method according to claim 1, wherein the pore size of the first membrane filter is 0.4 to 0.5 μm; the unit volume amount of the first filtration is 4 to 6 mL; and the first filtration step is repeated 2 to 4 times.

6. The method according to claim 1, wherein the pore size of the first membrane filter is 0.4 to 0.5 μm; the unit volume amount of the first filtration is 4 to 6 mL; and the first filtration step is repeated 6 or more times.

7. The method according to claim 1, further comprising, prior to the step (A):
(a-1) a step of preparing a carbon nanotube dispersion by sonicating a mixture comprising carbon nanotubes, a surfactant, and a dispersion medium; and
(a-2) a step of separating metallic carbon nanotubes and semiconducting carbon nanotubes from the carbon nanotube dispersion.

8. The method according to claim 6, wherein the step of separating metallic carbon nanotubes and semiconducting carbon nanotubes comprises separating the carbon nanotube dispersion into a precipitate comprising metallic carbon nanotubes and a supernatant comprising semiconducting carbon nanotubes by centrifugation.

9. The method according to claim 1, wherein the step (C) further comprises:
(c-1) a step of placing the second membrane filter with the carbon nanotube thin film deposited thereon on a substrate and pressing to attach the carbon nanotube thin film to the substrate; and
(c-2) a step of placing the substrate with the carbon nanotube thin film attached thereto into a reflux chamber and dissolving and removing the second membrane filter;
wherein the second membrane filter is dissolved with vapor of at least one selected from the group consisting of acetone, tetrahydrofuran, and a mixture thereof.

10. The method according to claim 1, wherein the carbon nanotubes are at least one selected from the group consisting of single-walled carbon nanotubes, double-walled carbon nanotubes, multi-walled carbon nanotubes, and a mixture thereof.

11. The method according to claim 6, wherein the mass ratio of the carbon nanotubes to the surfactant is 1:0.5-1.5.

12. The method according to claim 6, wherein the surfactant is at least one selected from the group consisting of FMN (Flavin mononucleotide), FC12 (N-dodecyl flavin), FC16 (N-hexadecyl flavin), FC20 (N-eicosyl flavin), and mixtures thereof.

13. The method according to claim 6, wherein the dispersion medium is at least one selected from the group consisting of water, ethanol, methanol, acetone, dimethylformamide, dimethyl sulfoxide (DMSO), benzene, toluene, xylene, xylene isomers, ethyl acetate, tetrahydrofuran, pyridine, hexane, N-methyl-2-pyrrolidone, and mixtures thereof.

14. A thermoelectric device comprising a carbon nanotube film manufactured according to claim 1.
